(19) United States
(12) Patent Application Publication
(10) Pub. No.: US 2004/0183124 A1
(43) Pub. Date: Sep. 23, 2004

(54) Flash memory device with selective gate within a substrate and method of fabricating the same

(75) Inventors: Cheng-Yuan Hsu, Hsinchu City (TW); Chih-Wei Hung, Hsinchu City (TW); Chi-Shan Wu, Shindian City (TW); Vincent Huang, Hsinchu City (TW)

Correspondence Address: LADAS & PARRY, 5670 WILSHIRE BOULEVARD, SUITE 2100, LOS ANGELES, CA, 90036-5679, US

(73) Assignee: Powerchip Semiconductor Corp.

(21) Appl. No.: 10/666,118

(22) Filed: Sep. 19, 2003

(30) Foreign Application Priority Data
Mar. 20, 2003 (TW) 92106140

(51) Int. Cl. H01L 29/788

(52) U.S. Cl. 257/316

(57) ABSTRACT

A flash memory device with selective gate within a substrate and method of fabricating the same. The flash memory device comprises a substrate with a floating gate disposed thereon. A wordline extends along a first direction and overlies the floating gate and the adjacent substrate thereof. A trench is disposed in the substrate adjacent to one side of the wordline. A selective gate is vertically disposed in the trench, partially covering the floating gate. A source region is disposed in the substrate adjacent to the other side of the wordline and a drain region is disposed in the substrate beneath the selective gate.

### BACKGROUND OF THE INVENTION 1. Field of the Invention

The present invention relates to a semiconductor device and method of fabricating the same. More particularly, it relates to a flash memory device with a selective gate within a substrate and the method of fabricating the same. 2. Description of the Related Art Flash memory is a type of erasable programmable read-only memory (EPROM), which in turn is a type of non-volatile memory. One of the advantages of flash memory is its capacity for block-by-block memory erasure. Furthermore, the speed of memory erasure is fast, and normally takes just 1 to 2 seconds for the complete removal of a whole block of memory. Therefore, in recent years, flash memory has been widely utilized in electrical consumer products, such as digital cameras, digital video cameras, cellular phones, laptop computers, mobile cassette players, and personal digital assistants (PDA).

In general, each cell of the flash memory includes two gates. One of the gates, known as a floating gate, is used for charge storage. The second gate, known as a control gate, controls the input and output of data. The floating gate is located beneath the control gate, and is generally in a floating state because there is no connection with external circuits. The control gate is normally wired to the word line.

Each of the memory cells can be electrically programmed (charged) by having electrons injected from the drain region through the oxide layer onto the floating gate. The charge can be removed from the floating gate by tunneling the electrons to the source through the oxide layer during an erase operation. Thus the data in a memory cell is determined by the presence or absence of a charge on the floating gate and the described operations. Thus, operations of a memory cell can be achieved by applying different operating voltages onto a control gate, a source region, a drain region and the substrate thereof. In some cases, split-gate types are used in the memory cell structures of the flash memory to increase the operational efficiency thereof.

FIG. 1 is a schematic cross-section of a conventional split-gate flash memory device 10 having N-type doped source region 20 and drain region 22 in a P-substrate 12 with a floating gate 14 between a control gate electrode 16 and the substrate 12, both of which overlap the source region 20 and a portion of the channel between the source region 20 and the drain region 22. In addition, a selective gate 18 is further formed on the control gate 16, and extends to a portion of the channel not covered by the floating gate 14 and the control gate 16 as an addressing electrode. Erasure of the device 10 is achieved by applying about 50 volts on the control gate 16 to remove electrons from the floating gate 14 through the dielectric (not shown) between the floating gate 14 and the control gate 16 by Fowler-Nordheim tunneling. Due to the presence of the addressing gate (referring to the selective gate 18), the device 10 will not leak current even if the floating gate transistor is over-erased because the addressing electrode can still turn off the device 10. Thus, frequencies for erasing and writing the flash memory device 10 and lifetime thereof are both increased. The structure as shown in FIG. 1 effectively includes a floating gate 14 and an addressing electrode (referring to the selective gate 18) in series and is referred to as a split gate structure.

The selective gate 18 within the split gate flash memory needs to cover the surface between the floating gate and the drain region (or source region). Thus, the split gate flash memory usually has a larger cell size and cannot achieve the modern design rule of reduced size of the cell structures and increased cell integration.

### SUMMARY OF THE INVENTION

Accordingly, an object of the invention is to provide a flash memory device that can achieve high integration of memory cells thereof.

Another object of the invention is to provide a method of fabricating a flash memory device with selective gate within a substrate, wherein the size of the memory device thereof can be reduced.

Thus, a flash memory device with selective gate within a substrate in accordance with the present invention comprises a substrate with a floating gate disposed thereon. A wordline extends along a first direction overlying the floating gate and the adjacent substrate thereof. A trench is disposed in the substrate adjacent to one side of the wordline. A selective gate is vertically disposed in the trench partially covering the floating gate. A source region is disposed in the substrate adjacent to the other side of the wordline and a drain region is disposed in the substrate beneath the selective gate.

Furthermore, the method of fabricating the flash memory device with selective gate within a substrate in accordance with the present invention comprises providing a substrate, sequentially depositing a first dielectric layer and a first conductive layer thereon, defining the first conductive layer, forming an active area extending along a first direction, sequentially depositing a second dielectric layer, a second conductive layer and a cap layer on the substrate, covering the active area, defining the cap layer and the second conductive layer, forming a wordline pattern extending along a second direction and partially covering the active area, forming a pair of spacers respectively disposed on both sides of the wordline pattern to form a wordline, etching the second dielectric layer and the first conductive layer exposed by the wordline, forming a control gate within the portion of the wordline in the active area, etching the substrate at one side of the wordline to form a trench therein, forming a drain region in the substrate beneath the trench, sequentially forming a third dielectric layer and a third conductive layer on one sidewall and portions of the bottom of the trench, partially covering the floating gate, to vertically form a selective gate in the trench and forming a source region in the substrate at the other side of the wordline, electrically contacting the floating gate.

In the present invention, the split gate flash memory device is partially formed on the substrate. Thus, the size thereof can be reduced and integration increased. The memory device of the invention thus achieves higher integration of memory cell capacity than in the Prior Art.

In addition, the flash memory device of the invention is a split gate flash memory device with a selective gate within a substrate for preventing effects of over-erased floating gate transistor. Thus, frequencies for erasing and writing the flash memory device and lifetime thereof are both increased. A flash memory device with better performance is thus provided by the invention.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a schematic cross-section of the split gate flash memory device of the Prior Art;

FIGS. 2A˜2L are schematic cross-sections of the fabricating process of the invention; and

FIGS. 3A˜3F are schematic top views of corresponding cross-sections for one embodiment of the invention.

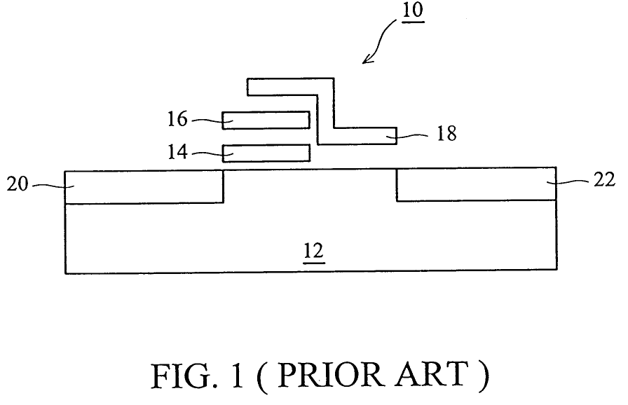

### DETAILED DESCRIPTION OF THE INVENTION

The present invention provides a flash memory device with a selective gate within a substrate meeting demands for increased capacity of memory cells.

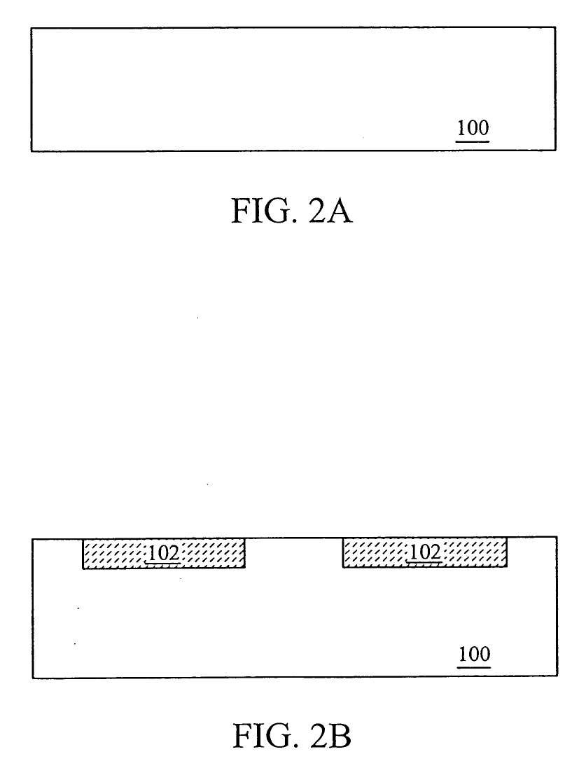

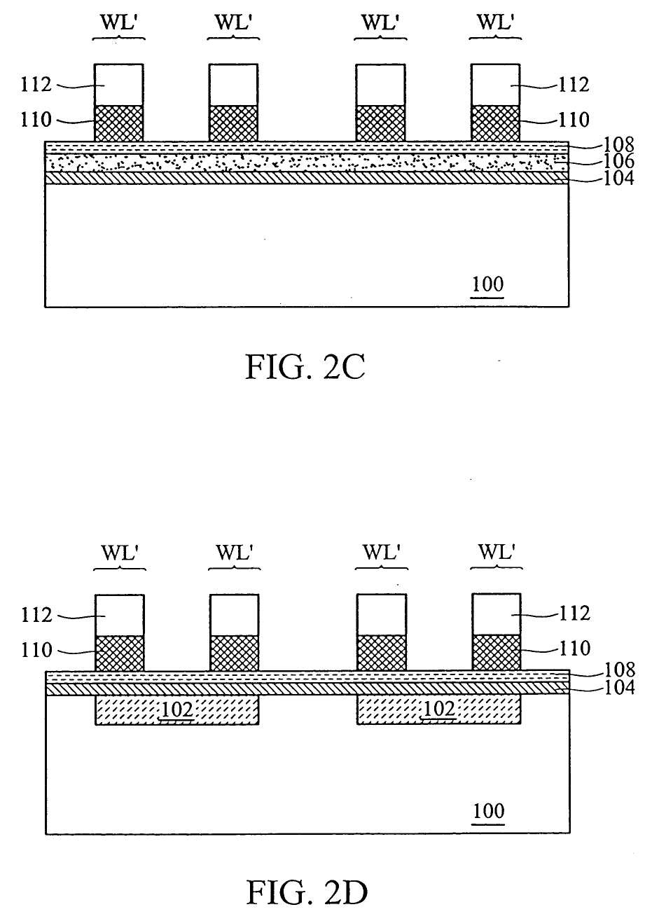

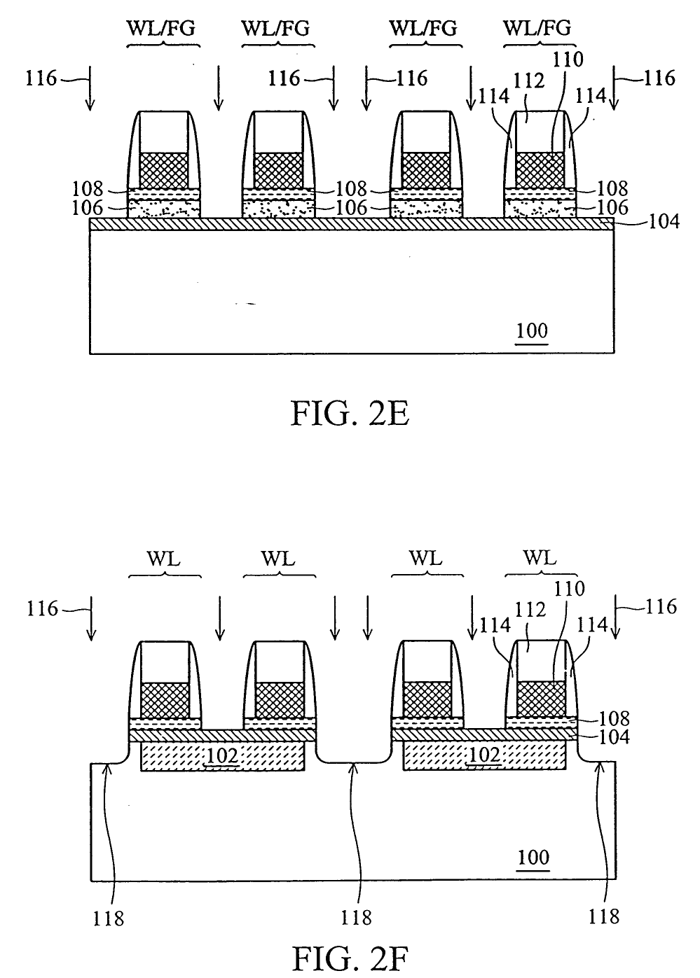

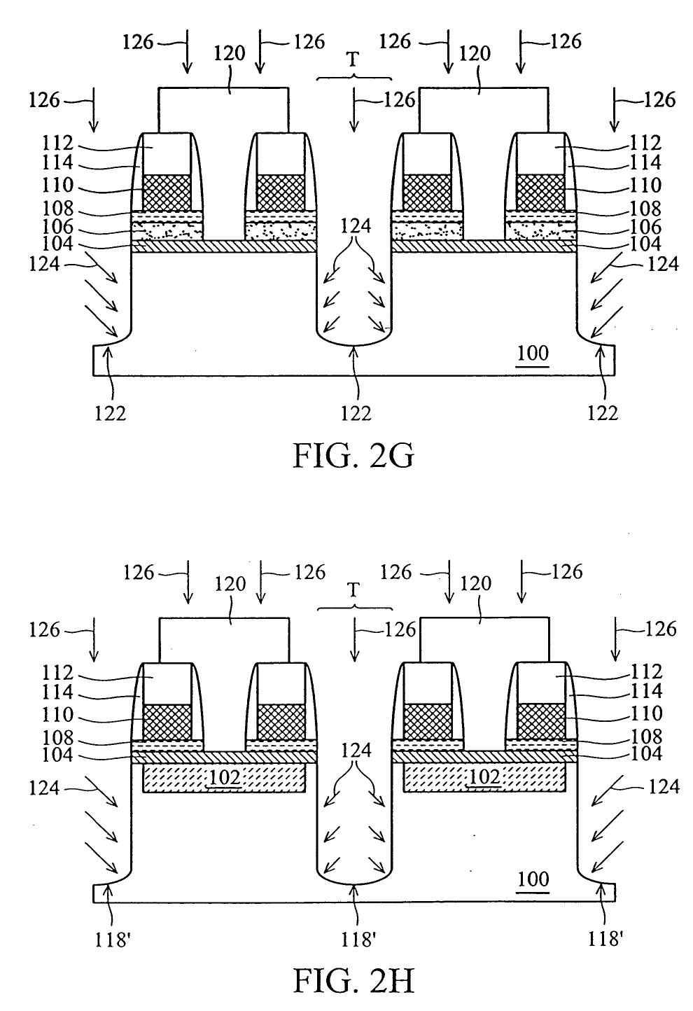

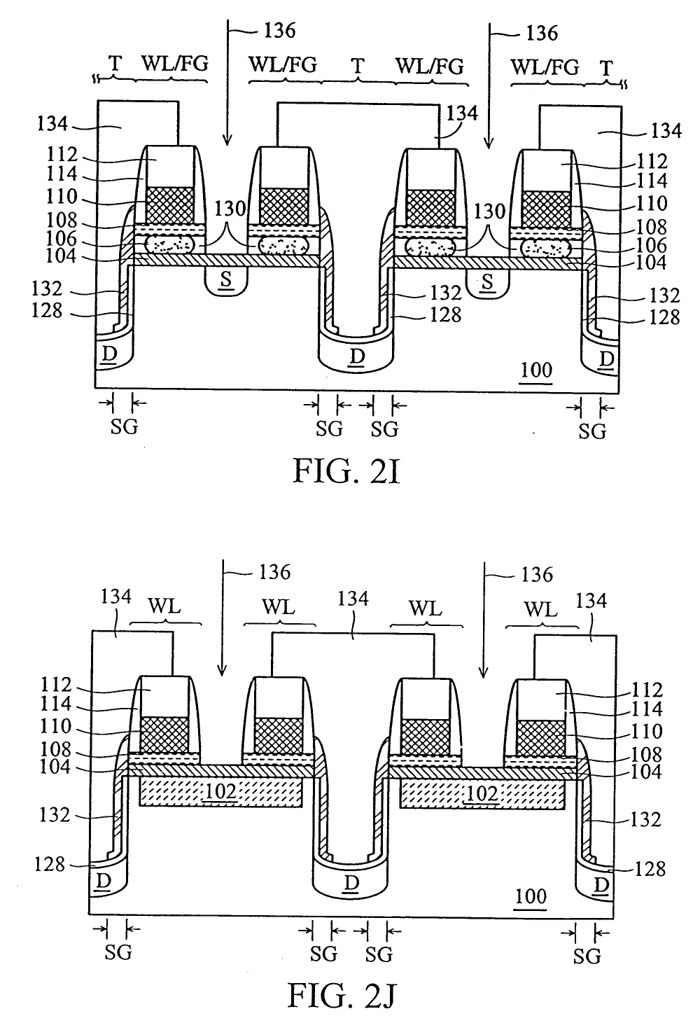

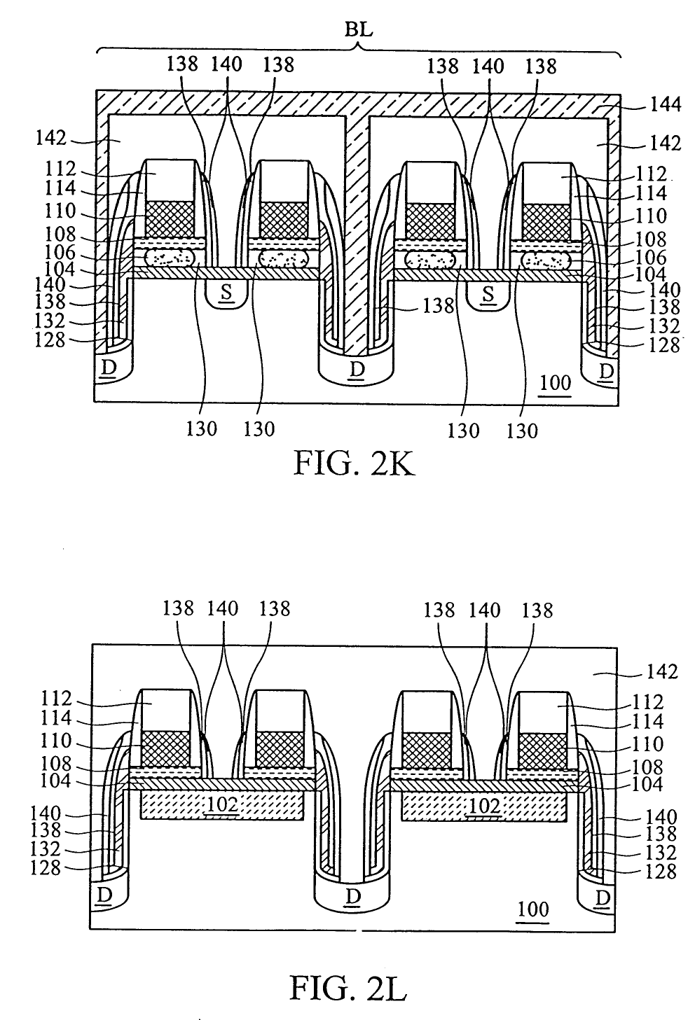

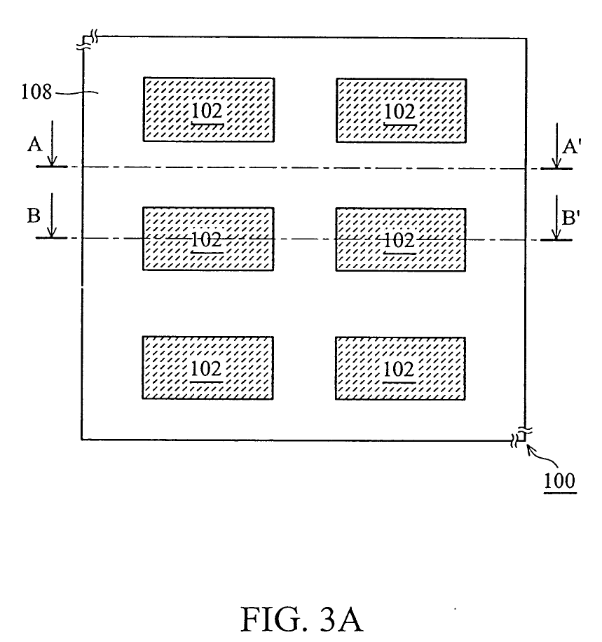

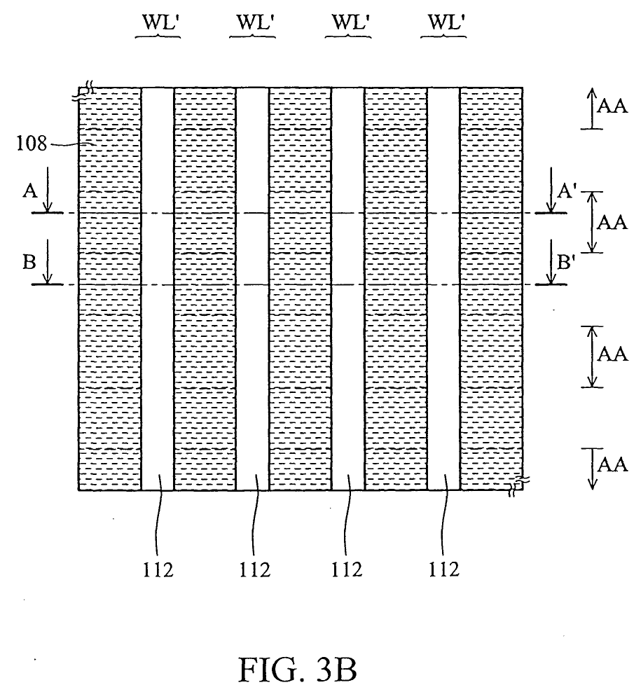

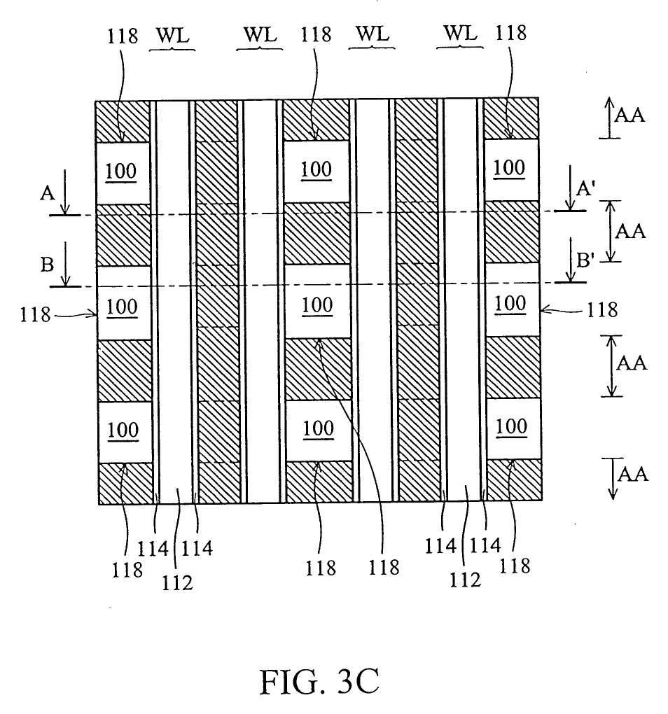

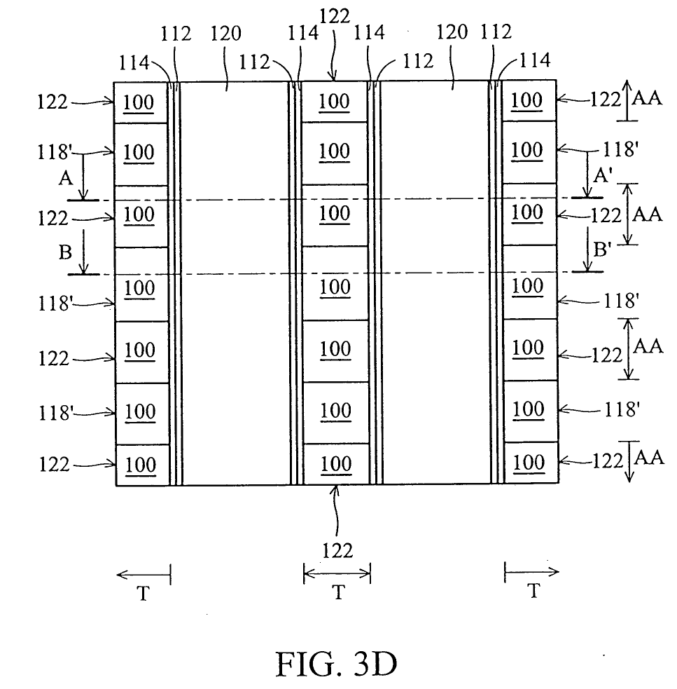

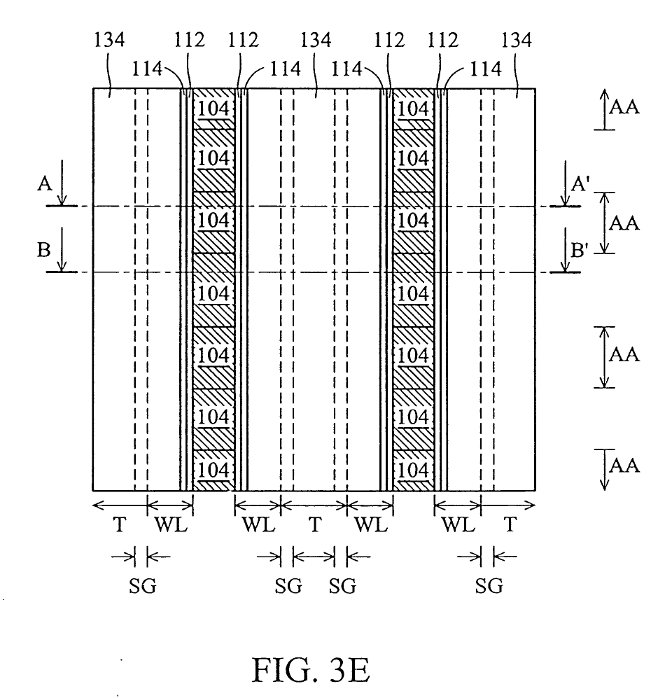

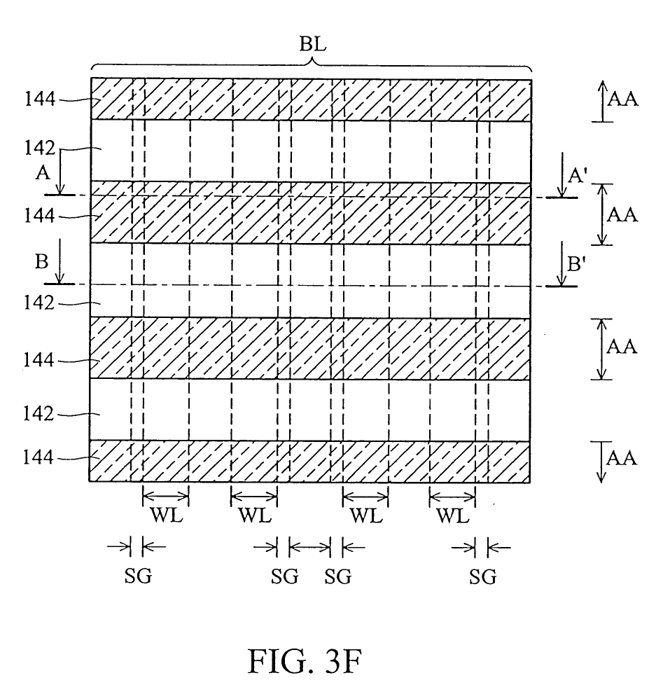

FIGS. 2A˜2L respectively illustrate the schematic cross-sections of a fabricating process along lines A˜A′ and lines B˜B′ according to an embodiment of the present invention. Moreover, FIGS. 3A˜3F also illustrate corresponding top views of the fabricating process.

In FIGS. 2A, 2B and 3A, a semiconductor substrate 100, for example a P-type silicon substrate, is provided. In the substrate 100, a plurality of isolation regions 102 are formed therein by, for example, conventional shallow trench isolation (STI) technique. The arrangement of these isolation regions 102 is repeated and the distance therebetween can substantially be the same. Thus, a top view of the substrate 100 with these isolations 102 therein is illustrated in FIG. 3A, in which a plurality of crisscross surfaces formed by the surrounding isolation regions 102 are shown. FIGS. 2A and 2B respectively illustrate a cross-section along lines A˜A′ and B˜B′ in FIG. 3A.

In FIGS. 2C, 2D and 3B, a first dielectric layer 104 and a first conductive layer 106 are sequentially deposited on the substrate 100 and the isolation regions 102 therein. Next, the first conductive layer 106 is defined by subsequent lithography and etching (not shown) and stopped on the first dielectric layer 104. Thus, a plurality of active areas AA are formed and extended along a first direction parallel to the direction of line A˜A′ in FIG. 3B. The exposed crisscross surfaces of the substrate 100 (not shown) are covered by the active area AA along the described first direction. The isolation regions 102 adjacent to the active area are also partially covered by the active areas AA. The first dielectric layer 104 can be comprised of, for example, silicon dioxide formed by chemical vapor deposition (CVD) as a tunnel oxide here. The thickness thereof can be between 85Å and 100Å. The first conductive layer 106 can be comprised of, for example, polysilicon formed by CVD with thickness between 400Å and 700Å.

Next, a second dielectric layer 108, a second conductive layer 110 and a cap layer 112 are sequentially deposited on the substrate 100, covering the active areas AA and the first dielectric layer 104 exposed by the active areas AA thereon. The cap layer 112 and the second conductive layer 110 are defined by subsequent lithography and etching (not shown) and stopped on the second dielectric layer 108. Thus, a plurality of wordline patterns WL′ are formed and extend along a second direction perpendicular to the line A˜A′ in FIG. 3B, partially covering the active areas AA. The cap layer 112 can be comprised of, for example, silicon nitride formed by CVD and the thickness thereof is between 500Å and 1500Å. The second dielectric layer 108 can be comprised of, for example, a conventional oxide-nitride-oxide (ONO) composite film or silicon dioxide formed by low pressure chemical vapor deposition (LPCVD). The second dielectric layer 108 performs as an inter-gate dielectric with thickness between 600Å and 2000Å. This top view is shown in FIG. 3B, and FIGS. 2C and 2D respectively illustrate a cross-section along lines A˜A′ and B˜B′ therein.

In FIGS. 2E, 2F and 3C, a first spacer 114 is formed on both sides of the wordline patterns WL′ by sequential deposition and etching of a conformal layer of insulating material such as silicon nitride. Thus, wordlines WL respectively include a wordline pattern WL′ and the first spacers 114 thereby are formed. Next, an etching process 116, for example dry etching, is performed to etch the second dielectric layer 108 and first conductive layer 106 exposed by the wordlines WL using the wordlines WL as the etching mask. Thus, a plurality of floating gates FG are formed in the active areas AA covered by the individual wordline WL. During the etching process 116, the second dielectric layer exposed by the wordlines WL is removed. The first dielectric layer 104 between active areas AA and the substrate 100 therebelow cannot avoid etching during the etching process 116. Thus, first trenches 118 with a depth between 500Å and 1000Å are formed in the substrate 100 between the active areas AA. Portions of each wordline WL covering each floating gate FG perform as a control gate here. This top view is shown in FIG. 3C, and FIGS. 2E and 2F respectively illustrate a cross-section along lines A˜A′ and B˜B′ thereof.

In FIGS. 2G, 2H and 3D, a patterned mask 120 formed by, for example, photoresist (PR) materials, is formed on every two adjacent wordlines WL on the same isolation region 102. Next, an etching process (not shown), for example dry etching, is performed to etch the substrate 100 between the patterned mask 120 including that of the first trenches 118 formed between the active areas AA. Thus, a trench T is formed in the substrate 100 at one side of the wordlines WL. Each trench T is composed of a second trench 122 with a depth between 800Å and 1200Å in the substrate 100 under the active area AA and a first trench 118′ deepened by the described etching process between the active areas having a depth between 1300Å and 2500Å alternatively disposed in the substrate 100.

Next, a tilt angle (7 to 300°) threshold voltage (Vt) implantation 124 and a 0 angle drain implantation 126 are respectively performed on the sidewalls of the trenches T a to adjust the threshold voltage and form a drain region (not shown) in the substrate 100 below the bottom of the trenches T. This top view is shown in FIG. 3D, and FIGS. 2G and 2H respectively illustrate a cross-section along lines A˜A′ and B˜B′ thereof.

In FIG. 2I, 2J and 3E, after the removal of the patterned mask 120, a thermal annealing process (not shown) is performed to form a drain region D in the substrate 100 beneath the trenches T. Next, a thermal oxidation (not shown) is performed to oxidize the surfaces of the trench T, forming a third dielectric layer 128 comprised of silicon dioxide thereon. The thickness thereof is between 120Å and 200Å. During the described oxidation, portions of the first conductive layer 106 on both sides thereof are also oxidized and an oxide layer 130 with width between 130Å and 300Å is formed on both sides of the first conductive layer 106. Next, a third conductive layer 132 is formed on both sidewalls of the wordline WL by sequential deposition and etching of a layer of conductive material such as polysilicon. The thickness thereof is between 200Å and 500Å. The third conductive layer 132 is partially covered on the third dielectric layer 128 disposed in the trench T and contacts a portion of the wordline WL and the oxide layer 130 disposed adjacent to the first conductive layer 106 within the floating gate FG. Next, another patterned mask 134 formed by, for example photoresist (PR) materials, is formed in the trench T and onto the two adjacent wordlines WL thereof. Next, an etching process (not shown), for example dry etching, is performed to etch the third conductive layer 132 relying on the two adjacent wordlines WL disposed on the same isolation regions 102. Thus, a selective gate SG including the third dielectric layer 128 and the third conductive layer 132 disposed in the trench T, extending along the direction parallel to the wordlines WL, is formed. Next, a source implantation 136 is performed to form a source region S in the substrate 100 between every two wordlines WL disposed on the same isolation region 102. This top view is shown in FIG. 3E, and FIGS. 2I and 2J respectively illustrate a cross-section along lines A˜A′ and B˜B′ therein.

In FIGS. 2K, 2L and 3F, after the removal of the patterned mask 134, a second spacer 138 and a third spacer 140, covering the third conductive layer 132 within the trench T, are sequentially formed on both sides of the wordline WL. Materials of the second spacers 134 and the third spacers 138 can respectively be, for example, silicon oxide and silicon nitride. Next, an inter-layer dielectric (ILD) layer 142 is formed on the wordlines WL and fills the trenches T. Next, metal lines, extending along a first direction perpendicular to that of the wordlines WL, include suitable contact structures (referring to the metal layer 144) with the drain regions in the trenches T therein formed. This top view is shown in FIG. 3F, and FIG. 2K and 2L respectively illustrate a cross-section along lines A˜A′ and B˜B′ thereof.

In FIG. 2K, a cross-section of the structure of the flash memory device with selective gate within a substrate in accordance of the present invention is shown. The flash memory device comprises a substrate (referring to the P-type silicon substrate 100). A floating gate (referring to the first dielectric layer 104 and the first conductive layer 106 covered by the wordline WL) is disposed on the substrate. A wordline (referring to the stack including the cap layer 112, the second conductive layer 110, the second dielectric layer 108 and the first spaces 114) extends along a first direction and overlies the floating gate and the adjacent substrate thereof. A trench (referring to the trench T) is disposed in the substrate adjacent to one side of the wordline. A selective gate (including the third conductive layer 132 and the third dielectric layer 128) vertically disposed in the trench, partially covering the floating gate. A source region S is disposed in the substrate adjacent to the other side of the wordline and a drain region D is disposed in the substrate under the selective gate.

Compared with the split gate flash memory device of the Prior Art, the present invention has the following advantages.

First, the selective gate performing an addressing electrode of the flash memory device in accordance with the invention is vertically disposed in a trench thereby rather than being normally disposed on the surface of a substrate as in the Prior Art. The split gate flash memory device of the present invention is partially formed on the substrate. Thus, size thereof can be reduced and integration increased. The memory device of the invention thus achieves higher integration of memory cell capacity than that the Prior Art.

In addition, the flash memory device of the invention is a split gate flash memory device with a selective gate within a substrate for preventing effects of over-erased floating gate transistor. Thus, frequencies for erasing and writing the flash memory device and lifetime thereof are both increased. A flash memory device with better performance is thus provided by the invention.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A flash memory device with selective gate within a substrate, comprising:
a substrate;
a floating gate disposed on the substrate;
a wordline extending along a first direction and overlying the floating gate and the adjacent substrate thereof;
a trench disposed in the substrate adjacent to one side of the wordline;
a selective gate vertically disposed in the trench and partially covering the floating gate;
a source region disposed in the substrate adjacent to the other side of the wordline; and
a drain region disposed in the substrate beneath the selective gate.

2. The flash memory device as claimed in claim 1, wherein the floating gate further comprises a first dielectric layer and a first polysilicon layer, sequentially stacked on the substrate.

3. The flash memory device as claimed in claim 2, further comprising an oxide layer with a width between 130Å and 220Å disposed on both sides of the first polysilicon layer such that one thereof contacts the selective gate.

4. The flash memory device as claimed in claim 1, further comprising a control gate formed by the portion of the wordline overlying the floating gate.

5. The flash memory device as claimed in claim 1, wherein the wordline extends along a first direction is composed of a second dielectric layer, a second conductive layer and a cap layer.

6. The flash memory device as claimed in claim 5, further comprising a spacer disposed on both sides of the cap layer.

7. The flash memory device as claimed in claim 1, wherein the selective gate further comprises a third dielectric layer and a third conductive layer, and the third dielectric layer formed on one sidewall and portions of the bottom of the trench.

8. The flash memory device as claimed in claim 1, wherein the trench extends along a first direction and has a depth between 800Å and 1200Å.

9. The flash memory device as claimed in claim 7, wherein the third dielectric layer is between 120Å and 200Å.

10. The flash memory device as claimed in claim 7, wherein the third conductive layer is between 200Å and 500Å.

11. A method of fabricating a flash memory device with selective gate within a substrate, comprising the steps of:
providing a substrate;
sequentially depositing a first dielectric layer and a first conductive layer on the substrate;
defining the first conductive layer, to form an active area extending along a first direction;
sequentially depositing a second dielectric layer, a second conductive layer and a cap layer on the substrate, and covering the active area;
defining the cap layer and the second conductive layer, to form a wordline pattern extending along a second direction and partially covering the active area;
forming a pair of spacers respectively disposed on both sides of the wordline pattern to form a wordline;
etching the second dielectric layer and the first conductive layer exposed by the wordline, to form a control gate within the portion of the wordline in the active area;
etching the substrate at one side of the wordline to form a trench therein;
forming a drain region in the substrate beneath the trench;
sequentially forming a third dielectric layer and a third conductive layer on one sidewall and portions of the bottom of the trench, and partially covering the floating gate, to vertically form a selective gate in the trench; and
forming a source region in the substrate at the other side of the wordline, and electrically contacting the floating gate.

12. The method as claimed in claim 11, wherein the method for forming the third dielectric layer is thermal oxidation.

13. The method as claimed in claim 12, wherein when forming the third dielectric layer, an oxide layer is formed on both sides of the second conductive layer within the floating gate.

14. The method as claimed in claim 13, wherein the oxide layer has a thickness between 130Å and 220Å.

15. The method as claimed in claim 11, wherein the trench has a depth between 800Å and 1200Å.

16. The method as claimed in claim 11, wherein the first direction is substantially perpendicular to the second direction.

17. The method as claimed in claim 11, wherein the third dielectric layer is formed on the sidewall and portions of the bottom of the trench.
